(19) United States
(12) Patent Application Publication
(10) Pub. No.: US 2007/0132081 A1
(43) Pub. Date: Jun. 14, 2007

(54) Multiple stacked die window csp package and method of manufacture

(75) Inventors: Chuen Khiang Wang, Singapore (SG); Hien Boon Tan, Singapore (SG); Koon Hwee Joanne Teo, Singapore (SG); Sin Nee Song, Singapore (SG); Koon Tian Edmund Lua, Singapore (SG)

Correspondence Address: GREENBLUM & BERNSTEIN, P.L.C., 1950 ROLAND CLARKE PLACE, RESTON, VA, 20191, US

(73) Assignee: UNITED TEST AND ASSEMBLY CENTER LIMITED, Singapore (SG)

(21) Appl. No.: 10/598,514

(22) PCT Filed: Mar. 3, 2005
(86) PCT No.: PCT/SG05/00067

§ 371 Date: Jan. 29, 2007

Related U.S. Application Data
(60) Provisional application No. 60/549,153, filed on Mar. 3, 2004.

(51) Int. Cl. H01L 23/02

(52) U.S. Cl. 257/686; 257/E23.085

(57) ABSTRACT

A semiconductor package including a first substrate having a die receiving area, a first adhesive layer, a window opening, and a plurality of conductive traces, a first semiconductor die having two sides and with an electrically active side mounted to the substrate through the first adhesive layer, a second adhesive layer having a first side attached to an electrically inactive side of the first semiconductor die, a second substrate having a die receiving area and a plurality of conductive traces and terminals, a last adhesive layer having a first side attached to a side of the second substrate with the terminals, a last semiconductor die having two sides and with an electrically inactive side being mounted to the second side of the third adhesive layer, and an electrically active side being electrically coupled to the conductive traces of the first or second substrate directly or through a redistribution device, and an encapsulant to encapsulate the semiconductor dies and electrical coupling, and signal transferring interconnects to transfer an electrical signal from the conductive traces to the exterior of the package.

The present application expressly incorporates by reference herein the entire disclosure of U.S. Provisional Patent Application No. 60/549,153, filed Mar. 3, 2004, entitled “Multiple Stacked Die Window CSP Package And Method Of Manufacture”.

### BACKGROUND OF THE INVENTION

1. Field of the Invention

The present invention generally relates to the field of semiconductor Integrated Circuit (IC) packaging, and more particularly, to the field of multi-chip packaging.

2. Description of the Related Art

The rapid growth of portable electronics and the wireless communications industry is driving the electronics packaging industry's research and development efforts to develop many breakthroughs and inventions.

A development of the electronics packaging industry is multi-chip packaging. This is primarily driven by industry demand to package more functional silicon content into smaller packages and at lower cost. Packaging two or more silicon integrated circuits within the IC package body reduces the area required and related cost on the printed circuit boards, on which the IC packages are mounted. Additionally, multi-chip packaging enables closer proximity and shorter electronic signal paths between the chips in the package. This reduces electronic signal travel time and improves overall speed and performance. Additionally, the chip scale package (CSP) is a package which is only modestly larger than the integrated circuit chip or die which is encapsulated by the package.

One of the multi-chip packaging techniques of the prior art is to stack silicon chips vertically to achieve a smaller planar form or footprint, as shown in FIG. 1. Interconnections between chips and the external terminals of the package can be achieved by conventional wire bonding, bumps in flip chip fashion, lead bonding, or combinations of these techniques. However, there are still presently several fundamental difficulties in prior art chip stacking relating to stacking of chips of similar size and special bond pad layout designs.

For chips of similar size and their corresponding bond pads arranged in a nonperipheral manner, for example in SDRAM chips where the bond pads are arranged along the center line of the chip, the similar size chips cannot be stacked directly on each other because the bond pads on the bottom chip would be blocked when the next chip is stacked thereon. See FIG. 2. This makes connections by wire bonding, for example, out of the chip to the external terminals of the package impossible.

One of the techniques used for vertically stacking center row bond pad chips is to have the bottom chip's active surface facing the interposer substrate with a cut out window. The bond pads of the bottom chip are connected out to the circuit of the interposer substrate through a substrate window by fine wires. The top chip is stacked on the backside of the bottom chip with the active surface facing away from the interposer substrate, i.e., in back to back format. See FIG. 3, which shows the first and last die stacked back to back to each other; the first and last dies are similar in size and have the same bond pad layout. The bond pads are laid out in single row in-line along the centerline of die. Bond pads on the last die are redistributed to the periphery of the die. To facilitate short wire bonding connections from the bond pads of the top chip to the circuitry of the substrate, some redistribution techniques are being employed to bring he wire connections to the periphery of the top chip. This technique is disclosed in U.S. Patent Application Publication No. 2003/0197284 to United Test & Assembly Center Limited.

The invention disclosed in U.S. Patent Application Publication No. 2003/0197284 is suitable for, e.g., single row bond pad layout because when the active surface of the chip is either facing upwardly or downwardly, the bond pads can be connected to either peripheral side of the chip. However, if the bond pads are arranged in two or more rows, as shown in FIG. 2, the orientation of the bond pads of the chip facing downwardly and that of the chip facing upwardly are direct mirror images of each other especially in memory devices, the corresponding bond pads of similar chips must be connected to a set of common package external pins. This will result in crossing wires between the two rows of bond pads either for the top chip or the bottom chip.

Due to the window opening on the substrate, the routing of the conductive traces through the window opening is limited. Conductive traces need to be diverted around the window opening if it is necessary to route from one side of the substrate to another, resulting in longer electrical signal paths.

### SUMMARY OF THE INVENTION

The present invention is directed to a novel multi-chip package and a novel method of multi-chip packaging that overcome problems and difficulties existing in the prior art. More particularly, the present invention overcomes problems in the prior art that involves chips of similar or identical size and chips having a non-perpheral multiple row bond pad layout. The present invention also provides the design and process of manufacture of the multi-chip package.

It is an object of the present invention to provide a device and method to overcome difficulties of image orientation of the bond pad layouts between the two similar chips and routing difficulties of the substrate. The present invention allows a die back to die back stacking arrangement.

An aspect of the present invention provides a structure of a semiconductor package with a first substrate having a die receiving area and window opening and a plurality of conductive traces, a second substrate with a plurality of conductive traces, a first adhesive layer, a second adhesive layer, a last adhesive layer, a first semiconductor die having a plurality of bond pads and a last semiconductor die having a plurality of bond pads. The first semiconductor die, having two sides, with the electrically active side being mounted to the first substrate through the first adhesive layer within the die receiving area, is electrically coupled to the conductive traces. A second adhesive layer has its first side attached to the inactive side of the first semiconductor die. The second substrate has either a single signal layer or multiple signal layers with at lest one of the signal layers facing away from the second adhesive layer and having a die receiving area. The last semiconductor die, having two sides, has an electrically inactive side mounted to the second substrate through the last adhesive layers within the die receiving area. Signal transferring interconnections such as, for example, wire bonding, are used for transferring electrical signals from the conductive traces to the package exterior and vice versa.

### BRIEF DESCRIPTION OF THE DRAWINGS

The above, and other objects, features and advantages of the present invention will be made apparent from the following description of the preferred embodiments, given as nonlimiting examples, with reference to the accompanying drawings in which:

FIG. 1 is a cross sectional view of a stacked die multi-chip package of the prior art;

FIG. 2 is a perspective view of a two row centerline bond pad layout semiconductor chip of the prior art;

FIG. 3 is a cross sectional view of a two die high density package of the prior art;

FIG. 4 is a cross sectional view of a two die high density package according to a first embodiment of the present invention;

FIG. 5 is a perspective view of the two die high density package according to the embodiment of FIG. 4;

FIG. 6 is a cross sectional view of multiple dies arranged in stacked format according to a second embodiment of the present invention;

FIG. 7 is a cross sectional view of a multiple die high density package according to an alternative embodiment of FIG. 4,

FIG. 8 is a cross sectional view of a multiple die arranged in stacked format according to an alternative embodiment of FIG. 4;

FIG. 9 is a cross sectional view of a multiple die arranged in stacked format according to a third embodiment of the present invention;

FIG. 10 is a cross sectional view of a multiple die arranged in stacked format according to a fourth embodiment of the present invention;

FIG. 11A shows a conductor trace routing and its terminals using a single conductor layer for the second substrate;

FIG. 11B shows a conductor trace routing and its terminals using two conductor layers;

FIG. 11C is a cross sectional view of a second substrate pre-prepared such that the laminate substrate or lead-frame is strengthened by adhering to a more rigid material; and

FIG. 12 shows a method of manufacture of the two die high density package according to the embodiment of FIG. 4.

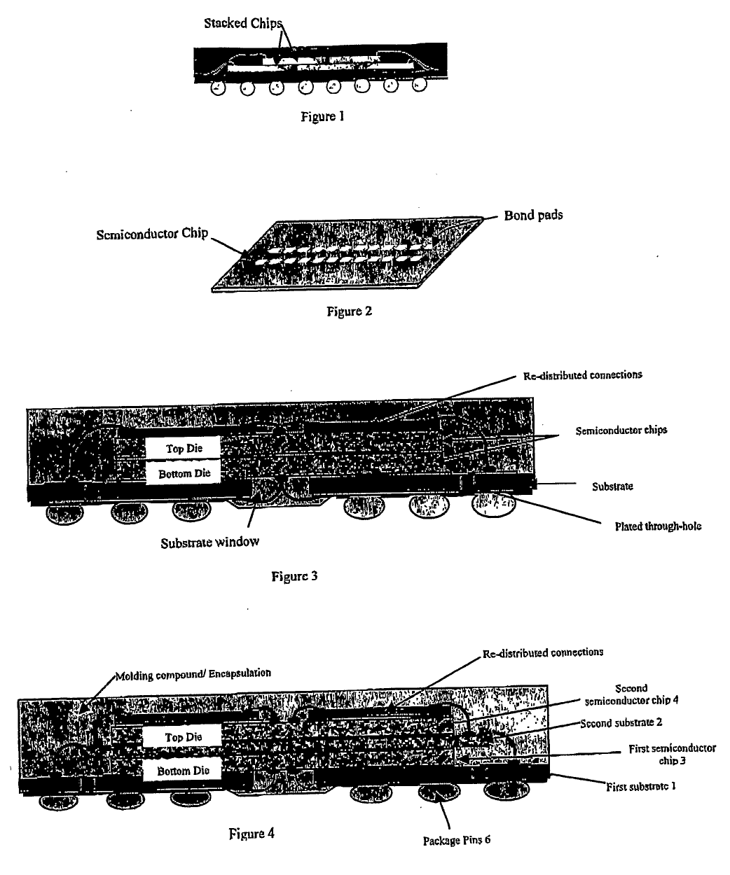

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

With reference to the drawings, FIG. 4 shows a two die high density package according to a first embodiment of the present invention. The two die high density package of the first embodiment includes a semiconductor package with a first substrate 1 having a die receiving area and window opening and a plurality of conductive traces, a second substrate 2 with a plurality of conductive traces 5, a first adhesive layer, a second adhesive layer, a last adhesive layer, a first semiconductor die 3 having a plurality of bond pads and a last semiconductor die 4 having a plurality of bond pads. The first or bottom semiconductor die 1, having two sides, with the electrically active side being mounted to the first substrate 1 through the first adhesive layer within the die receiving area, is electrically coupled to the conductive traces. A second adhesive layer has its first side attached to the inactive side of the first semiconductor die 3. The second substrate 2 has either a single signal layer or multiple signal layers with at least one of the signal layers facing away from the second adhesive layer and having a die receiving area. The last or top semiconductor die 4, having two sides, has an electrically inactive side mounted to the second substrate 2 through the last adhesive layers within the die receiving area. Signal transferring interconnections such as, for example, wire bonding, are used for transferring electrical signals from the conductive traces to the package exterior and vice versa. The second substrate 2 functions as an avenue for signal paths to avoid any complication of interconnections crossing each other and to convey the signals to the underside of the package for easy connection to the package pins 6 or between the bond pads of the first and the last die.

In the embodiment of FIG. 4, the bond pad layout for the last or top die 4 is arranged in two rows in-line along the centerline of the die as shown in FIG. 2, The second substrate 2 is sandwiched between the inactive side of the first 3 and last die 4. Bond pads on the last die are redistributed to the periphery of the die.

As shown in FIG. 5, the package according to the first embodiment includes fine wires to connect the two rows of bond pads of the last die 4 to circuitry in the redistribution layers. Further, fine wires are included to connect the redistribution layers to the conductor traces in the second substrate 2. The conductor traces in the second substrate 2 convey the signals from one side of the last die 4 to the opposite side of the last die 4 or any other sides of the last die 4. Fine wires are included also to connect the second substrate 2 to the first substrate 1. Circuitry in the first substrate 1 conveys the signals from the second substrate 2 to the package pins 6. Additionally, the same package pins 6 can be connected to the corresponding or similar assignment bond pads of the first die 3.

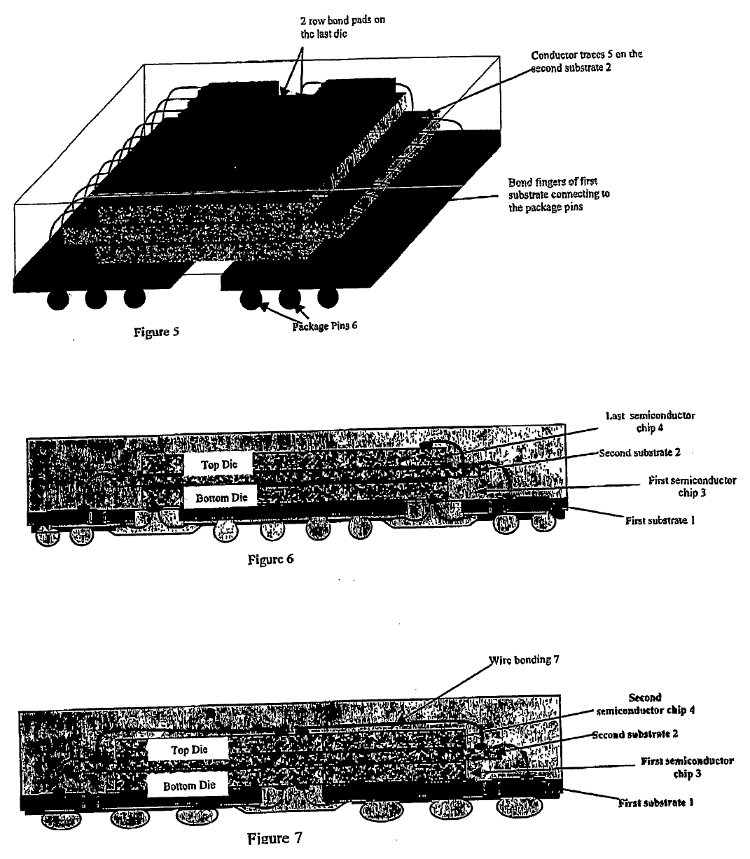

A second embodiment of the present invention is shown in FIG. 6. In the second embodiment, the first die 3 includes a bond pad layout arranged along the periphery of the die. Further, the bond pads of the last die 4 are arranged in the periphery of the die, and the conductor traces in the second substrate 2 convey the signals from one side of the last die 4 to the opposite side of the last die 4 or any other sides of the last die 4.

An alternative embodiment of the package of the present invention is shown in FIG. 7. In the alternative embodiment, the two die high density package includes direct wire bonding 7 from the last die to the second substrate without redistribution devices on the last die 4.

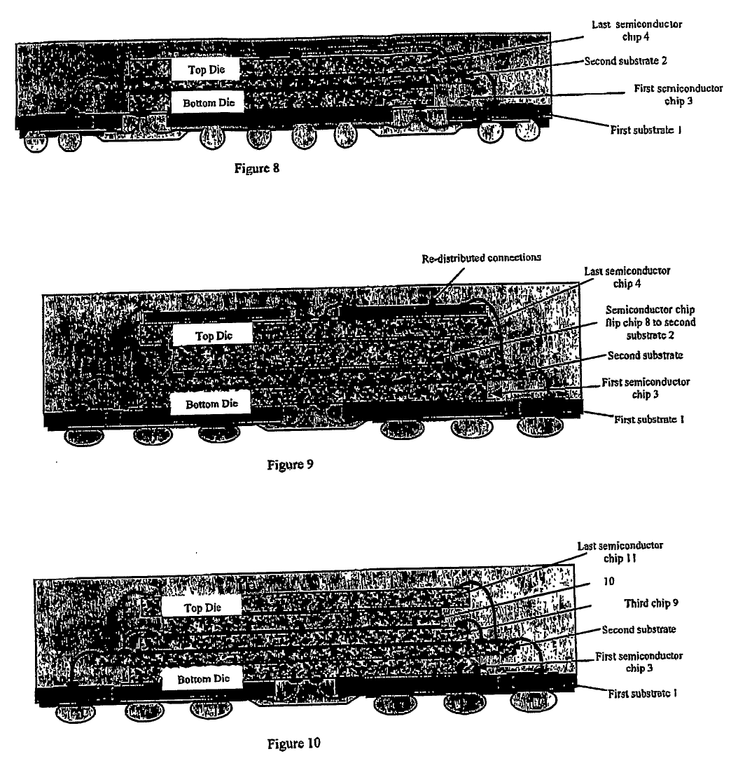

A further alternative embodiment of the package of the present invention is shown in FIG. 8. In this alternative embodiment, the first die 3 has a bond pad layout arranged along the periphery of the die. Further, the last die 4 may not be identical to the first die 3, and the bond pads of the last die 4 may be arranged near or along the centerline of the die. Additionally, the conductor traces in the second substrate 2 convey the signals from one side of the last die to the opposite side of the last die or any other sides of the last die.

A third embodiment of the package of the present invention is shown in FIG. 9. In the third embodiment of the package, a semiconductor die 8 is flipped onto the second substrate 2, forming a flip chip die. Further, the last semiconductor die 4 is attached to the inactive side of the flip-chip die.

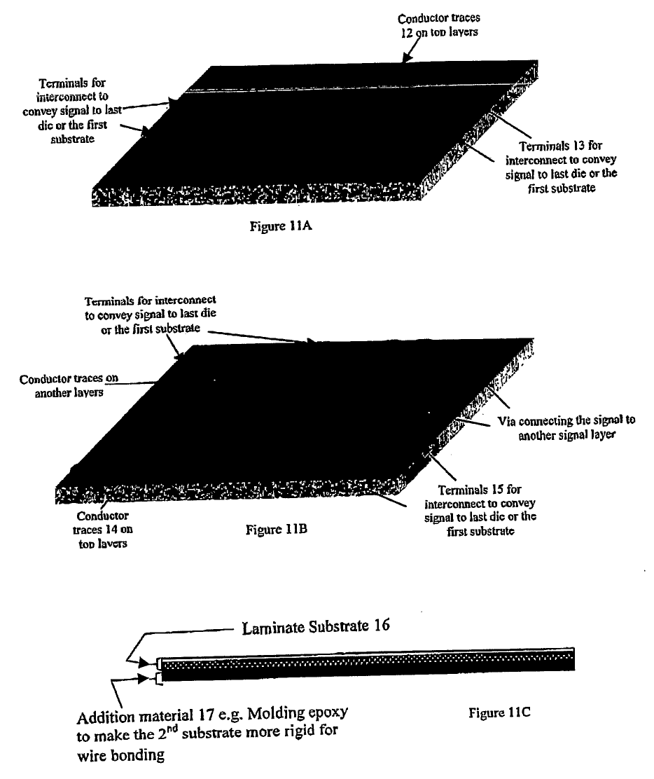

A fourth embodiment of the package of the present invention is shown in FIG. 10. In the fourth embodiment, a spacer 10 is provided to separate the two semiconductor dies 9, 11 whose active sides are facing away from the package pins.

FIG. 11A shows the conductor trace routing 12 and its terminals 13 using a single conductor layer for the second substrate 2. The interconnects convey signals to and from the last die 4 or the first substrate 1 through the terminals along the two sides of the second substrate. FIG. 11B shows the conductor trace routing 14 and its terminals 15 using two conductor layers. The interconnects convey signals to and from the last die or the first substrate through the terminals on any side of the second substrate. FIG. 11C shows a second substrate 2 prepared such that the laminate substrate or lead-frame 16 is strengthened by adhering to a more rigid material 17.

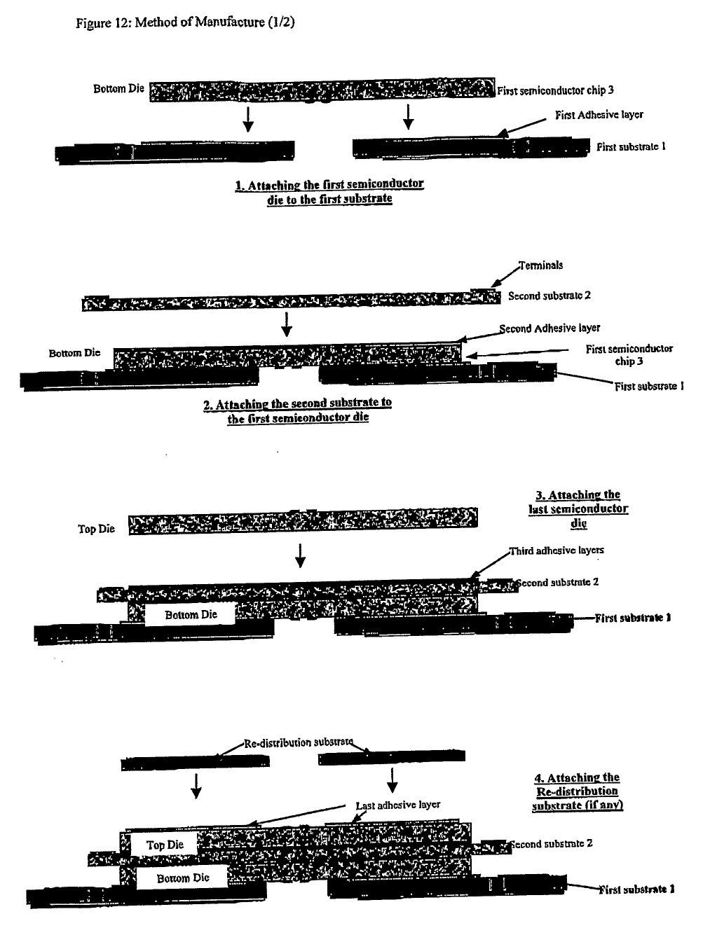

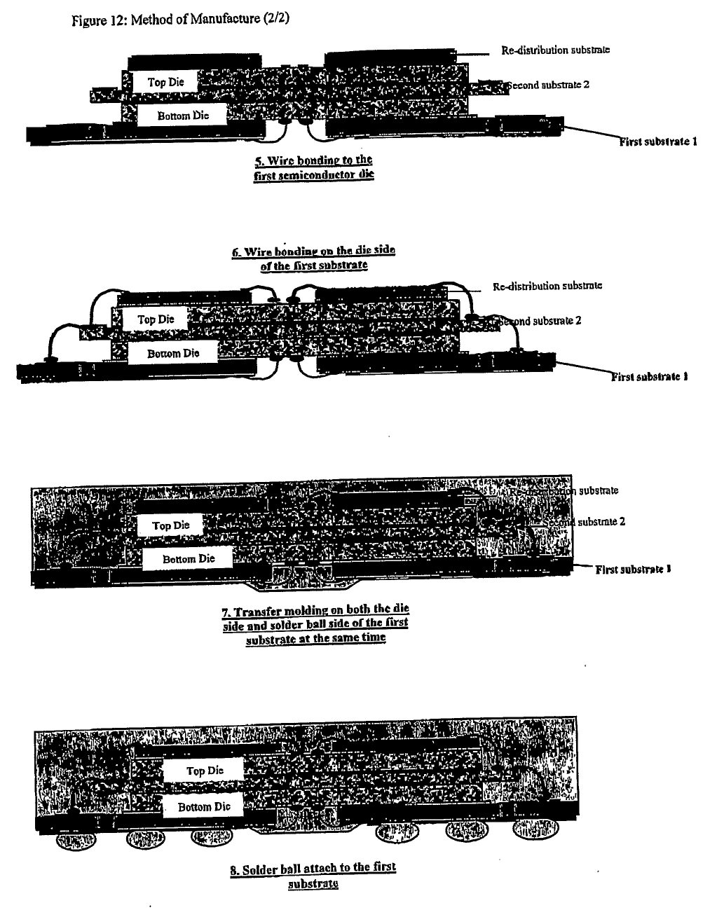

FIG. 12 shows steps of a method of manufacture of the two die high density package according to the first embodiment of the present invention.

Additionally, in the semiconductor package according to the present invention, the first semiconductor die includes a plurality of bond pads, and the bond pads are positioned within the window opening of said first substrate, Alternatively, the first semiconductor die includes a plurality of bond pads, and the bond pads are not positioned within the window opening of said first substrate, the bond pads being electrically relocated to the window opening by a redistribution device. The bond pads may be positioned near the periphery of said last semiconductor die.

Further, the last semiconductor die has a plurality of bond pads, and the bond pads are not positioned near the periphery of the last semiconductor die, the bond pads being electrically relocated to the periphery of the last semiconductor die by a redistribution device. The redistribution device includes a wafer redistribution layer. The redistribution device includes a metallic interposer with a plurality of conductive traces, attached to the active surface of the last semiconductor die with an adhesive, with a plurality of electrical couplings from the bond pads to the metallic interposer. Alternatively, the redistribution device includes a metallic interposer with a plurality of conductive traces, attached to the active surface of the last semiconductor die with an adhesive, and a plurality of electrical couplings from the bond pads to the metallic interposer.

The adhesive layer may be an adhesive paste or coating, or an adhesive film. Further, the size of the first semiconductor die may be smaller, equal to, or greater than the size of the last semiconductor die. The electrical coupling from the first semiconductor die to the first substrate is by wire bond. Further, the electrical coupling from the first semiconductor die to the first substrate is by a TAB (tape automated bonding) method.

Further, the semiconductor package may include direct wire bonding from the bond pads of the last semiconductor die to the first or second substrate without going through any redistribution device, as shown in FIGS. 7 and 8. The first semiconductor die is electrically coupled to the first substrate by a flip chip method Further, the last semiconductor die is electrically coupled to the second substrate by a flip chip method. The last semiconductor die is stacked with an inactive side facing an inactive side of a flip chip semiconductor die on the second substrate. Further, the second substrate is formed of any of the following materials including silicon, ceramic, laminate, aluminum, and any material that can be manufactured with a plurality of conductor traces. The second substrate is formed of a thin laminate, a flexible circuit, or a lead-frame and processed to increase rigidity for attachment and an electrical interconnection process, such as for example, by adding molding compound to the side of the substrate that is going to face the second adhesive layer, as shown in FIG. 11C.

The semiconductor package may include a second substrate having terminals along its periphery allowing interconnects to convey electrical signals to and from the last semiconductor die and the first substrate at any side of the last semiconductor die. Further, the second substrate includes a plurality of conductive traces having the terminals positioned in optimum positions along its periphery such that when wire bonding from the terminal positions to the first substrate allow the shortest paths to the package external pins. The second substrate includes a plurality of conductive traces having the terminals positioned in optimum positions along its periphery such that wire bonding from the terminal positions to the first substrate allow shortest paths to the interconnection from the first semiconductor die.

Further, a plurality of dies are positioned between the first and last semiconductor die, whereby a semiconductor die between the first and last semiconductor die are electrically coupled to the first or second substrate. The size of the plurality of dies can be smaller, equal to, or greater than the size of the first or last semiconductor die.

The semiconductor package further includes a spacer in the stacking of the semiconductor dies. The window opening includes a plurality of openings in the first substrate coinciding with the bond pads of the first semiconductor die.

Additionally, the encapsulant may be any suitable material such as, for example, a liquid encapsulant, or a transfer molded molding compound. The encapsulant is applied to the package to cure. Alternatively, the encapsulant includes a lid to cover the semiconductor die and electrical coupling. Further, the adhesive layers can be pre-attached to a receiving area or to the respective matching side of the part to attach to the receiving area.

Although the invention has been described with reference to an exemplary embodiment, it is understood that the words that have been used are words of description and illustration, rather than words of limitation. Changes may be made within the purview of the appended claims, as presently stated and as amended, without departing from the scope and spirit of the invention in its aspects. Although the invention has been described with reference to particular means, materials and embodiments, the invention is not intended to be limited to the particulars disclosed. Rather, the invention extends to all functionally equivalent structures, methods, and uses such as are within the scope of the appended claims.

1. A semiconductor package comprising:
a first substrate having a die receiving area, a first adhesive layer, a window opening, and a plurality of conductive traces;
a first semiconductor die, having an electrically active side and an electrically inactive side, the electrically active side being mounted to said first substrate through the first adhesive layer at the die receiving area, to electrically couple said first semiconductor die to the plurality of conductive traces;
a second adhesive layer having a first side attached to an electrically inactive side of said first semiconductor die;
a second substrate having a die receiving area, a plurality of conductive traces and a side with terminals;
a third adhesive layer having a first side attached to the side of said second substrate with the terminals;
a last semiconductor die, having an electrically active side and an electrically inactive side, the electrically inactive side being mounted to a second side of said third adhesive layer, and the electrically active side being electrically coupled to said conductive traces of said first or second substrate directly or through a redistribution device;
an encapsulant to encapsulate said semiconductor dies and electrical coupling; and
signal transferring interconnections to transfer an electrical signal from said conductive traces to an exterior of the package.

2. The semiconductor package according to claim 1, wherein said first semiconductor die includes a plurality of bond pads, whereby said bond pads are positioned within the window opening of said first substrate.

3. The semiconductor package according to claim 1, wherein said first semiconductor die includes a plurality of bond pads, whereby said bond pads are not positioned within the window opening of said first substrate, said bond pads being electrically relocated to the window opening by a redistribution device.

4. The semiconductor package according to claim 1, wherein said last semiconductor die has a plurality of bond pads, whereby said bond pads are positioned near the periphery of said last semiconductor die.

5. The semiconductor package according to claim 1, where said last semiconductor die has a plurality of bond pads, whereby said bond pads are not positioned near the periphery of said last semiconductor die, said bond pads being electrically relocated to the periphery of said last semiconductor die by a redistribution device.

6. The semiconductor package according to claim 5, wherein said redistribution device includes a wafer redistribution layer.

7. The semiconductor package according to claim 5, wherein said redistribution device includes a metallic interposer with a plurality of conductive traces, attached to the active surface of the last semiconductor die with an adhesive, with a plurality of electrical couplings from the bond pads to the metallic interposer.

8. The semiconductor package according to claim 6, wherein said redistribution device includes a metallic interposer with a plurality of conductive traces, attached to the active surface of the last semiconductor die with an adhesive with a plurality of electrical couplings from the bond pads to the metallic interposer.

9. The semiconductor package according to claim 8, wherein said adhesive layer is an adhesive paste or coating.

10. The semiconductor package according to claim 8, wherein said adhesive layer is an adhesive film.

11. The semiconductor package according to claim 1, wherein the size of said first semiconductor die may be smaller, equal to, or greater than the size of said last semiconductor die.

12. The semiconductor package according to claim 1, wherein the electrical coupling from said first semiconductor die to said first substrate is by wire bond.

13. The semiconductor package according to claim 1, wherein the electrical coupling from said first semiconductor die to said first substrate is by a TAB method.

14. The semiconductor package according to claim 1, further comprising direct wire bonding from the bond pads of said last semiconductor die to the first or second substrate without going through any redistribution device.

15. The semiconductor package according to claim 1, wherein the first semiconductor die is electrically coupled to the first substrate by a flip chip method.

16. The semiconductor package according to claim 1, wherein said last semiconductor die is electrically coupled to said second substrate by a flip chip method.

17. The semiconductor package according to claim 1, wherein said last semiconductor die is stacked with an inactive side facing an inactive side of a flip chip semiconductor die on said second substrate.

18. The semiconductor package according to claim 1, wherein said second substrate is formed of any of the following materials including silicon, ceramic, laminate, aluminum, and any material that can be manufactured with a plurality of conductor traces.

19. The semiconductor package according to claim 1, wherein said second substrate is formed of a thin laminate, a flexible circuit, or a lead-frame and processed to increase rigidity for attachment and an electrical interconnection process.

20. The semiconductor package according to claim 1, wherein said second substrate has terminals along its periphery allowing interconnects to convey electrical signals to and from said last semiconductor die and said first substrate at any side of said last semiconductor die.

21. The semiconductor package according to claim 1, wherein said second substrate includes a plurality of conductive traces having the terminals positioned in optimum positions along its periphery such that wire bonding from the terminals to said first substrate allow shortest interconnection paths to the package external pins.

22. The semiconductor package according to claim 1, wherein said second substrate includes a plurality of conductive traces having the terminals positioned in optimum positions along its periphery such that wire bonding from the terminals to said first substrate allow shortest interconnection paths to the from said first semiconductor die to the terminals.

23. The semiconductor package according to claim 1, wherein a plurality of dies are positioned between said first and last semiconductor die, whereby a semiconductor die between said first and said last semiconductor die is electrically coupled to said first or second substrate.

24. The semiconductor package according to claim 23, wherein the size of said plurality of dies can be smaller, equal to, or greater than the size of said first or last semiconductor die.

25. The semiconductor package according to claim 1, further comprising a spacer in the stacking of the semiconductor dies.

26. The semiconductor, package according to claim 1, wherein said window opening comprises a plurality of openings in said first substrate coinciding with the bond pads of said first semiconductor die.

27. The semiconductor package according to claim 1, wherein said encapsulant is a liquid encapsulant.

28. The semiconductor package according to claim 1, wherein said encapsulant is a transfer molded molding compound.

29. The semiconductor package according to claim 1, wherein said encapsulant is applied to the package to cure.

30. The semiconductor package according to claim 1, wherein said encapsulant comprises a lid to cover said semiconductor die and electrical coupling.

31. The semiconductor package according to claim 1, wherein all the adhesive layers can be pre-attached to a receiving area or to a matching side of a part to attach to the receiving area.
